(19) United States
(12) Patent Application Publication
(10) Pub. No.: US 2015/0325534 A1
(43) Pub. Date: Nov. 12, 2015

(54) SEMICONDUCTOR PACKAGE FOR RADIO COMMUNICATION AND METHOD OF MANUFACTURING THE SAME

(71) Applicant: SAMSUNG ELECTRO-MECHANICS CO., LTD., Suwon-Si (KR)

(72) Inventor: Seong Yeon KIM, Suwon-Si (KR)

(73) Assignee: SAMSUNG ELECTRO-MECHANICS CO., LTD., Suwon-Si (KR)

(21) Appl. No.: 14/603,360

(22) Filed: Jan. 23, 2015

(30) Foreign Application Priority Data
May 9, 2014 (KR) 10-2014-0055638

(51) Int. Cl. H01L 23/66; H01L 21/50

(52) U.S. Cl. CPC H01L 23/66; H01L 21/50

(57) ABSTRACT

A semiconductor package for radio communication may include a substrate, and a plurality of electronic devices mounted on both surfaces of the substrate. The electronic devices running on the same frequency band among the plurality of electronic devices may be separately mounted on the both surfaces of the substrate. A method of manufacturing a semiconductor package for radio communication may include preparing a substrate, mounting at least one or more electronic devices on an upper surface of the substrate, and mounting at least one or more electronic devices on a lower surface of the substrate. The electronic devices of the same frequency band among the electronic devices may be separately mounted on the upper and lower surfaces of the substrate.

### CROSS REFERENCE(S) TO RELATED APPLICATIONS

This application claims the foreign priority benefit under 35 U.S.C. Section 119 of Korean Patent Application Serial No. 10-2014-0055638, entitled “Semiconductor Package For Radio Communication And Method Of Manufacturing The Same”, filed on May 9, 2014, which is hereby incorporated by reference in its entirety into this application.

### BACKGROUND

1. Technical Field

Some embodiments of the present disclosure relate to a semiconductor package for radio communication and a method of manufacturing the same.

2. Description of the Related Art

Recently, as a demand for high-speed and high-quality data transmission is increased, a demand in a radio communication technology to meet the demand has been continuously increased. A multiple input multiple output (MIMO) technology using a plurality of transmitting and receiving antennas has been receiving great attention recently.

The MIMO technology is a technology of performing communications using a plurality of streams through a plurality of antennas to more improve channel capacity than using a single antenna.

When the MIMO technology is applied to a communication module such as Wi-Fi module, and the like, a radio frequency (RF) line of the same frequency band and general electronic devices thereof (for example, RF switch, power amplifier, LNA, FEM, and the like) are generally disposed on the same one surface of a substrate in parallel. The reason is that the disposition design as described above may equally set a length between the RF paths to make wiring, a path loss or the like uniform, and therefore a module design may be easy.

However, in order for the MIMO technology to be normally operated, a correlation between each antenna port and the RF path may be designed to be minimized and thus signal interference thereof may be minimized. According to the module design as described above, if RF electronic devices using the same frequency band are physically separated from each other, the correlation between the RF signals of the same frequency band may be minimized.

Therefore, there is a need to develop a semiconductor package for radio communication and a method of manufacturing the same capable of having a wider separation distance between the RF electronic devices running on the same frequency band.

### SUMMARY

Some embodiments of a semiconductor package for radio communication and a method of manufacturing the same may be capable of having a wider separation distance between electronic devices using the same frequency band and minimizing a signal interference in the same frequency band.

According to an exemplary embodiment of the present disclosure, a semiconductor package for radio communication may include a substrate; and a plurality of electronic devices mounted on both surfaces of the substrate. The electronic devices running on the same frequency band among the plurality of electronic devices may be separately mounted on the both surfaces of the substrate.

A ground part may be formed between the both surfaces of the substrate.

The electronic device using the same frequency band may include: a first electronic device mounted on a first surface of the both surfaces of the substrate; and a second electronic device mounted on a second surface which is an opposite surface to the first surface. The second electronic device may be mounted in the remaining second surface area other than a second surface area corresponding to a mounting area of the first electronic device.

The second electronic device may be mounted in the second surface area in a diagonal direction to the first electric device.

The ground part may be formed between the first surface and the second surface of the substrate.

The semiconductor package may further include: a lower substrate having a cavity formed therein and bonded to a lower surface of the substrate so that the electronic devices mounted on the lower surface of the substrate are received in the cavity.

The lower substrate may be formed to be thicker than a mounting height of the electronic device mounted on the lower surface of the substrate.

The semiconductor package for radio communication may be used in a multiple input multiple output (MIMO) system.

According to another exemplary embodiment of the present disclosure, a method of manufacturing a semiconductor package for radio communication may include: preparing a substrate; mounting at least one or more electronic devices on an upper surface of the substrate; and mounting at least one or more electronic devices on a lower surface of the substrate. The electronic devices using the same frequency band among the plurality of electronic devices may be separately mounted on the upper and lower surfaces of the substrate.

The preparing of the substrate may include forming a ground part between the upper and lower surfaces of the substrate.

The mounting of the electronic devices on the upper surface may include mounting a first electronic device on the upper surface of the substrate. The mounting of the electronic devices on the lower surface may include mounting a second electronic device of the same frequency band as the first electronic device on the lower surface of the substrate. The second electronic device may be mounted in the remaining lower surface area other than a lower surface area corresponding to a mounting area of the first electronic device.

In the mounting of the second electronic device, the second electronic device may be mounted in a lower surface area in a diagonal direction to the first electronic device mounted on the upper surface of the substrate.

The preparing of the substrate may include forming a ground part between the upper and lower surfaces of the substrate.

The method of manufacturing a semiconductor package may further comprise mounting a lower substrate on the lower surface of the substrate along with the at least one electronic device.

In the mounting of the lower substrate, at least one electronic device may be mounted so that at least one electronic device may be received in a cavity formed on the lower substrate.

The lower substrate may be formed to be thicker than a mounting height of one or more electronic devices.

The method of manufacturing a semiconductor package for radio communication may be used in a multiple input multiple output (MIMO) system.

Additional aspects and/or advantages will be set forth in part in the description which follows and, in part, will be apparent from the description, or may be learned by practice of the invention.

### BRIEF DESCRIPTION OF THE DRAWINGS

These and/or other aspects and advantages will become apparent and more readily appreciated from the following description of the embodiments, taken in conjunction with the accompanying drawings of which:

FIG. 1 is a cross-sectional view schematically illustrating a semiconductor package for radio communication according to a first exemplary embodiment of the present disclosure.

FIGS. 2A through 2F are cross-sectional views for describing a method of manufacturing the semiconductor package for radio communication according to the first exemplary embodiment of the present disclosure.

FIG. 3 is a cross-sectional view schematically illustrating a semiconductor package for radio communication according to a second exemplary embodiment of the present disclosure.

FIGS. 4A through 4F are cross-sectional views for describing a method of manufacturing the semiconductor package for radio communication according to the second exemplary embodiment of the present disclosure.

### DESCRIPTION OF EMBODIMENTS

The acting effects and technical configuration with respect to the objects of a semiconductor package for radio communication and a method of manufacturing the same according to the present disclosure will be clearly understood by the following description in which some exemplary embodiments of the present invention are described with reference to the accompanying drawings.

Further, when it is determined that the detailed description of the known art related to the present invention may obscure the gist of the present invention, the detailed description thereof will be omitted. In the description, the terms first, second, and so on are used to distinguish one element from another element, and the elements are not defined by the above terms.

### First Exemplary Embodiment

### Semiconductor Package for Radio Communication

FIG. 1 is a cross-sectional view schematically illustrating a semiconductor package for radio communication according to a first exemplary embodiment of the present disclosure.

Referring to FIG. 1, a semiconductor package 100 for radio communication according to the first exemplary embodiment of the present disclosure may include a substrate 10 and one or more electronic devices 20. The semiconductor package 100 may be used in a multiple input multiple output (MIMO) system. However, the first exemplary embodiment of the present disclosure is not limited thereto and may be used in a single input single output (SISO) system, a single input multiple output (SIMO) system, a multiple input single output (MISO) system, and the like.

The electronic device 20 according to the first exemplary embodiment of the present disclosure may include one or a plurality of various electronic devices such as an active device and a passive device. In the first exemplary embodiment of the present disclosure, the electronic device 20 may include an RF line and general components thereof to which a multiple input multiple output technology is applied. However, the first exemplary embodiment of the present disclosure is not limited thereto and therefore, any radio communication related electronic device which may be mounted on the substrate 10 may be used as the electronic device 20.

The electronic devices 20 may be mounted on both surfaces of the substrate 10, for example, a first surface 11 and a second surface 12 of the substrate 10. The electronic devices 20 may be mounted on both surfaces of the substrate 10 in various forms according to a size or a shape of the electronic devices 20 and a design of the semiconductor package 100 for radio communication.

According to the semiconductor package 100 for radio communication according to the first exemplary embodiment of the present disclosure, at least one electronic device 20 may be mounted on each of the first surface 11 and the second surface 12 of the substrate 10, such that the plurality of electronic devices 20 may be mounted on both surfaces of the substrate 10.

In this case, according to the semiconductor package 100 for radio communication according to the first exemplary embodiment of the present disclosure, electronic devices 21a and 21b and 22a and 22b having the same frequency band among the plurality of electronic devices 20 may be separately mounted on both surfaces of the substrate 10.

In this case, according to the first exemplary embodiment of the present disclosure, the electronic devices mounted on the first surface (e.g., an upper surface in the first exemplary embodiment of the present invention) of the substrate 10 may be defined as “first electronic devices” 21a and 22a, and the electronic devices mounted on the second surface 12 (e.g., an opposite surface to the first surface, that is, a lower surface in the first exemplary embodiment of the present disclosure) of the substrate 10 using the same frequency band as the first electronic devices 21a and 22a may be defined as “second electronic devices” 21b and 22b. For example, in the first exemplary embodiment of the present disclosure, the electronic devices 21a and 21b may run on the 5 GHz band, and the electronic devices 22a and 22b may use the 2 GHz band, but is not limited thereto and therefore may adopt all the electronic devices of various frequency bands.

According to the first exemplary embodiment of the present disclosure having the configuration as described above, the RF electronic devices using the same frequency band may be separately mounted on both surfaces of the substrate 10, so that the RF electronic devices may have a wider separation distance for preventing signal interference than the case in which the RF electronic devices using the same frequency band are mounted on the same surface of the substrate.

Therefore, when the semiconductor package 100 for radio communication according to the first exemplary embodiment of the present disclosure is applied to the multiple input multiple output technology (technology of simultaneously transmitting and receiving a signal of the same frequency band), the signal interference in the same frequency band may be minimized.

Further, according to the first exemplary embodiment of the present disclosure having the configuration as described above, the electromagnetic interference of the RF electronic devices running on different frequency bands may be reduced.

As illustrated in FIG. 1, the second electronic device 21b according to the first exemplary embodiment of the present disclosure may be mounted in the remaining second surface area B′ other than a second surface area A′ corresponding to a mounting area A of the first electronic device 21a of the same frequency band. Similarly, another second electronic device 22b may also be mounted in the remaining second surface area A′ other than the second surface area B′ corresponding to a mounting area B of the first electronic device 22a using the same frequency band.

The case in which the second electronic device 21b or 22b is mounted on the second surface 12 of the substrate 10 by the above method may have a wider separation distance for preventing signal interference than the case in which the second electronic device 21b or 22b is mounted in the second surface area A′ or B′ corresponding to the mounting area A or B of the first electronic device 21a or 22a.

Further, in the case of the first exemplary embodiment, as illustrated in FIG. 1, the second electronic device 21b or 22b may be mounted in the second surface area B′ or A′ corresponding to the mounting area A or B of the first electronic device 21a or 22a in a diagonal direction. Thereby, the mounting method may ensure the wider separation distance.

Further, as described above, when the first electronic device 21a or 22a and the second electronic device 21b or 22b are mounted on both surfaces of the substrate 10 so as to correspond to each other in a diagonal direction, the RF paths to which the multiple input multiple output technology is applied are not entangled with each other and thus freedom of substrate layout may be improved.

Meanwhile, as the substrate 10 according to the first exemplary embodiment of the present disclosure, various types of substrates (for example, ceramic substrate, printed circuit board, flexible substrate, and the like) which are well known to the technical field of the present invention may be used.

Further, a mounting substrate 13 for mounting the electronic devices 20 or a wiring pattern (not illustrated) electrically connecting between the mounting electrodes 13 may be formed on both surfaces of the substrate 10.

Further, the substrate 10 according to the first exemplary embodiment of the present disclosure may be a multi-layer substrate formed of a plurality of layers, and a circuit pattern 14 for forming an electrical connection may be formed between the respective layers.

A ground part 15 may be formed on the first surface 11 and the second surface 12 of the substrate 10 according to the first exemplary embodiment of the present disclosure, that is, between both surfaces of the substrate 10.

As described above, when the ground part 15 is formed between both surfaces of the substrate 10, the ground part 15 may restrict the formation of a radiation pattern from the first electronic devices 21a and 22a to the second electronic devices 21b and 22b formed on an opposite surface thereto. Therefore, it is possible to more reduce the signal interference in the same frequency band.

Further, the substrate 10 according to the first exemplary embodiment of the present disclosure may include one or more mounting electrodes 13 formed on the upper surface thereof, one or more circuit patterns 14 formed in the substrate 10, and one or more conductive vias 16 electrically connecting between the electrode 13 and the circuit pattern 14.

In addition, an external connection pad 17 may be disposed on the lower surface of the substrate 10 according to the first exemplary embodiment of the present disclosure.

In this case, the external connection pad 17 may be electrically connected to a lower substrate 30 to be described below and may be connected to an external connection terminal 34 through the lower substrate 30. Therefore, the external connection pad 17 may be disposed at a position facing the upper surface of the lower substrate 30 when the lower substrate 30 on the lower surface of the substrate 10 is coupled with the substrate 10, and may be disposed in plural in various forms if necessary.

Meanwhile, as illustrated in FIG. 1, the semiconductor package 100 for radio communication according to the first exemplary embodiment of the present disclosure may further include the lower substrate 30. In this case, the lower substrate 30 may be boned to the lower surface of the substrate 10 and thus may be coupled with the substrate 10.

Further, the lower substrate 30 according to the first exemplary embodiment of the present disclosure may include a cavity 31 formed therein.

The cavity 31 may be used as a space in which the electronic devices mounted on the lower surface of the substrate 10, that is, the second electronic devices 21b and 22b are received.

Therefore, the electronic devices mounted on the lower surface of the substrate 10, that is, the second electronic devices 21b and 22b may be mounted at a position facing the cavity 31 of the lower substrate in the lower surface of the substrate 10 so that the second electronic devices 21b and 22b are received in the cavity 31.

Meanwhile, similar to the substrate 10, as the lower substrate 30, various types of substrates (for example, ceramic substrate, printed circuit board, flexible substrate, and the like) which are known to the technical field of the present disclosure may be used.

Further, an electrode pad 32 may be formed on both surfaces of the lower substrate 30. In this case, the electrode pad 32 formed on the upper surface of the lower substrate 30 may be formed to be electrically connected to the external connection pad 17 of the substrate 10. Further, the electrode pad 32 formed on the lower surface of the lower substrate 30 may be formed to be electrically connected to the external connection terminal 34.

Meanwhile, the wiring pattern (not illustrated) electrically connecting between the electrode pads 32 may also be formed on both surfaces of the lower substrate 30.

Similar to the substrate 10, the lower substrate 30 according to the first exemplary embodiment of the present disclosure may be a multi-layer substrate formed of a plurality of layers, and a circuit pattern (not illustrated) for forming an electrical connection may be formed between the respective layers.

Further, the lower substrate 30 may also include the electrode pads 32 formed on both surfaces thereof and the conductive vias 33 electrically connecting the circuit patterns formed in the lower substrate 30.

Further, the lower substrate 30 according to the first exemplary embodiment of the present disclosure may be formed at a thickness larger than a mounting height of the second electronic devices 21b and 22b mounted on the lower surface of the substrate 10 to stably protect the second electronic devices 21b and 22b received in the cavity 31. However, the first exemplary embodiment of the present disclosure is not limited thereto and the lower substrate 30 may also be formed at a thickness which is equal to or smaller than the mounting height of the second electronic devices 21b and 22b.

Further, the lower surface of the lower substrate 30 may be provided with the external connection terminal 34. The semiconductor package 100 for radio communication according to the first exemplary embodiment of the present disclosure may be electrically and physically connected to a main substrate (not illustrated) on which the semiconductor package 100 for radio communication may be mounted through the external connection terminal 34.

Further, the external connection terminal 34 may also be a signal transmission terminal which is electrically connected to the electronic devices 20. In this case, the external connection terminal 34 may electrically connect the electronic devices 20 to the main substrate. Therefore, the external connection terminal 34 may be formed in plural corresponding to the number, kind, or the like of electronic devices 20.

The external connection terminal 34 may be formed in a bump form, but the first exemplary embodiment of the present disclosure is not limited thereto and therefore the external connection terminal 34 may be formed in various forms such as a solder ball.

Further, the external connection terminal 34 as described above may be electrically connected to the electrode pads 32 formed on the upper surface of the lower substrate 30 through the via 33, and the like. Therefore, when the lower substrate 30 is coupled with the substrate 10, the substrate 10 may be electrically connected to the external connection terminal 34 through the lower substrate 30.

Meanwhile, as illustrated in FIG. 1, the semiconductor package 100 for radio communication according to the first exemplary embodiment of the present disclosure may further include a mold part 40. However, the first exemplary embodiment of the present disclosure is not limited thereto, and the configuration of the mold part 40 as described above is not necessarily required.

In this case, the mold part 40 may be formed on the upper surface of the substrate 10, and the first electronic devices 21a and 22a mounted on the upper surface of the substrate 10 may be sealed by the mold part 40.

The mold part 40 may be filled between the first electronic devices 21a and 22a mounted on the substrate 10 to be able to prevent an electric short from occurring between the first electronic devices 21a and 22a.

Further, the mold part 40 may be fixed on the upper surface of the substrate 10 while surrounding the outside of the first electronic devices 21a and 22a to be able to safely protect the first electronic devices 21a and 22a from an external impact.

The mold part 40 as described above may be made of, for example, but not limited to, an insulating material including a resin material such as epoxy. Further, the mold part 40 according to the first exemplary embodiment of the present disclosure may be formed by at least one or more steps of seating the substrate 10 having the first electronic devices 21a and 22a mounted on the upper surface 11 thereof in a mold (not illustrated) and injecting a forming resin in the mold. However, the first exemplary embodiment of the present disclosure is not limited thereto, and therefore the mold part 40 may be formed by various methods.

Meanwhile, in the semiconductor package 100 according to the first exemplary embodiment of the present disclosure, an insulating layer 50 may be formed between the substrate 10 and the lower substrate 30. However, the first exemplary embodiment of the present disclosure is not limited thereto, and the configuration of the insulating layer 50 as described above is not necessarily required.

In this case, the insulating layer 50 may be made of an insulating material and may be filled between the substrate 10 and the lower substrate 30 to be able to protect a conductive member (for example, bump, and the like) which electrically connects the substrate 10 to the lower substrate 30. Further, the insulating layer 50 may insulate the substrate 10 from the lower substrate 30 and may improve an adhesion between the substrate 10 and the lower substrate 30 to be able to increase reliability.

The insulating layer 50 may be made of an underfill resin. As a material of the insulating layer 50, epoxy resin, and the like may be used, but the first exemplary embodiment of the present disclosure is not limited thereto.

The first exemplary embodiment of the present disclosure describes, by way of example, the case in which the insulating layer 50 is formed only between the substrate 10 and the lower substrate 30, but is not limited thereto. For example, the insulating layer 50 may be formed between the substrate 10 and the second electronic devices 21b and 22b, and may also be formed over the lower surface 12 of the substrate 10.

<Method of Manufacturing Semiconductor Package for Radio Communication>

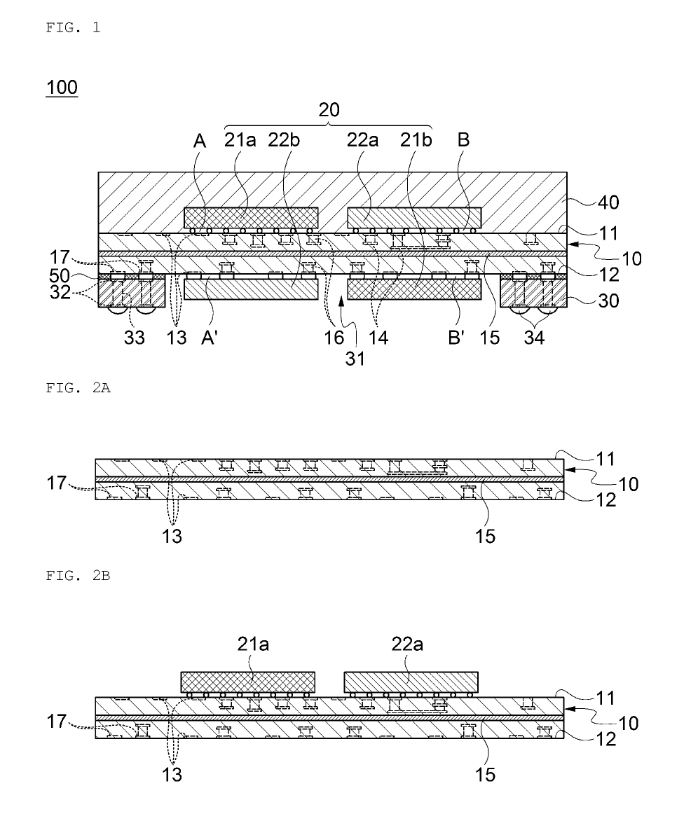

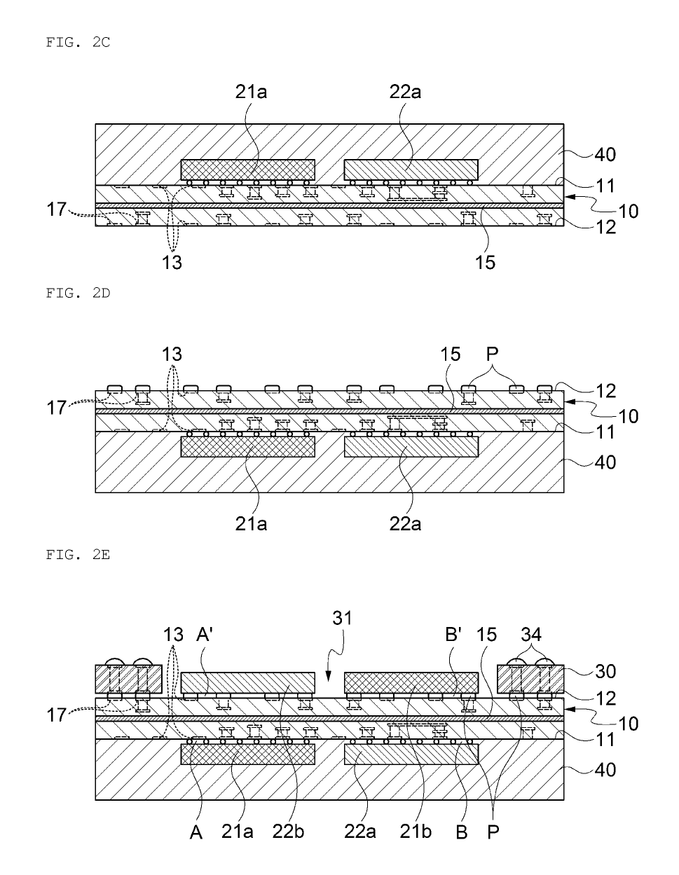

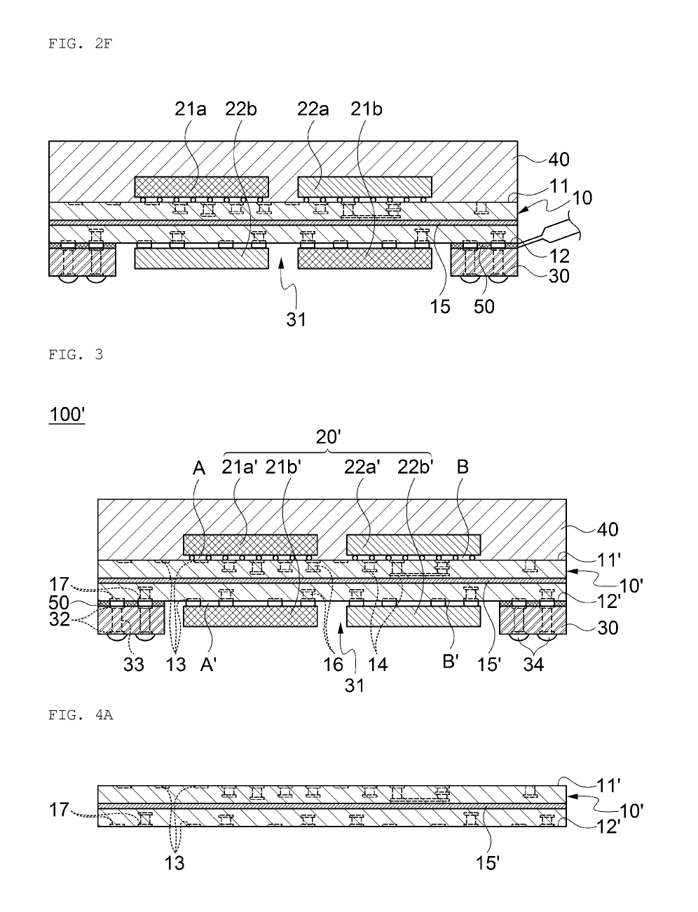

FIGS. 2A to 2F are cross-sectional views for describing a method of manufacturing the semiconductor package for radio communication according to the first exemplary embodiment of the present disclosure.

As illustrated in FIGS. 2A to 2F, the method of manufacturing the semiconductor package according to the first exemplary embodiment of the present disclosure may include preparing the substrate 10, mounting the electronic devices 20 on upper and lower surfaces of the substrate 10, and the like. For example, this method may be used in manufacturing the multiple input multiple output (MIMO) system. However, the first exemplary embodiment of the present disclosure is not limited thereto. The method of manufacturing the semiconductor package may be used in manufacturing a single input single output (SISO) system, a single input multiple output (SIMO) system, a multiple input single output (MISO) system, and the like.

First, as illustrated in FIG. 2A, the method of manufacturing a semiconductor package for radio communication according to the first exemplary embodiment of the present disclosure may include preparing the substrate 10.

Further, the substrate 10 prepared in the preparing of the substrate may be a multi-layer substrate. Both surfaces of the substrate 10 may be provided with the mounting electrodes 13 as described above. Further, the lower surface of the substrate 10 may be provided with the external connection pad 17.

The preparing of the substrate may further include forming a ground part 15 between the upper surface 11 and the lower surface 12 of the substrate 10. Therefore, the ground part 15 may be formed between both surfaces of the substrate 10 according to the first exemplary embodiment of the present disclosure.

Therefore, when the ground part 15 is formed between both surfaces of the substrate 10 by the foregoing process, the ground part 15 may limit the formation of the radiation pattern from the electronic device mounted on the upper surface 11 to the electronic device mounted on an opposite surface 12 (lower surface) thereto. Therefore, it is possible to more reduce the signal interference in the same frequency band.

Next, as illustrated in FIG. 2B, the method of manufacturing the semiconductor package for radio communication according to the first exemplary embodiment of the present disclosure may include mounting at least one of electronic device 21a and 22a on the upper surface 11 of the substrate 10.

In this configuration, the mounting of the electronic device on the upper surface of the substrate may include mounting the first electronic devices 21a and 22a on the upper surface 11 of the substrate 10.

For example, the mounting of the first electronic device may be performed by printing a solder paste on the mounting electrode 13 formed on the upper surface 11 of the substrate 10 using a screen printing method, and the like, seating the first electronic devices 21a and 22a thereon, and then applying heat to the solder paste to harden the solder paste.

Next, as illustrated in FIG. 2C, the method of manufacturing a semiconductor package for radio communication according to the first exemplary embodiment of the present disclosure may further include forming the mold part 40 on the upper surface 11 of the substrate 10. However, the first exemplary embodiment of the present invention is not limited thereto, but the forming of the mold part 40 is not necessarily performed.

As described above, the mold part 40 may be formed by disposing the substrate 10, on which the first electronic devices 21a and 22a are mounted, in the mold and then injecting a molding resin in the mold. Due to the formation of the mold part 40, the first electronic devices 21a and 22a mounted on the upper surface 11 of the substrate 10 may be protected from the outside of the semiconductor package 100 by the mold part 40.

Next, as illustrated in FIG. 2D, the method of manufacturing the semiconductor package for radio communication according to the first exemplary embodiment of the present disclosure may include printing solder paste P on the lower surface 12 of the substrate 10 on which the mold part 40 is formed.

In this case, the solder paste P may be printed on both the mounting electrode 13 and the external connection pad 17.

Next, as illustrated in FIG. 2E, the method of manufacturing the semiconductor package for radio communication according to the first exemplary embodiment of the present disclosure may include mounting at least one of electronic device 21b and 22b on the lower surface 12 of the substrate 10.

The mounting of the electronic device on the lower surface may include mounting the second electronic devices 21b and 22b of the same frequency band as the first electronic devices 21a and 22a on the lower surface 12 of the substrate 10.

By the method of manufacturing the semiconductor package for radio communication as described above, in particular, by the mounting of the electronic devices on the upper surface and the lower surface, the electronic devices 21a and 21b and 22a and 22b of the same frequency band among the plurality of electronic devices 20 may be separately mounted on the upper and lower surfaces (that is, both surfaces) of the substrate 10.

As a result, according to the first exemplary embodiment of the present disclosure as described above, the RF electronic devices of the same frequency band may be separately mounted on both surfaces of the substrate 10, which may have a wider separation distance for preventing the signal interference than the case in which the RF electronic devices of the same frequency band are mounted on the same one surface of the substrate.

Therefore, when the method of manufacturing the semiconductor package for radio communication according to the first exemplary embodiment of the present disclosure is applied to the multiple input multiple output technology (technology of simultaneously transmitting and receiving a signal of the same frequency band), the signal interference in the same frequency band may be minimized.

Further, as described above, according to the method of manufacturing the semiconductor package for radio communication according to the first exemplary embodiment of the present disclosure, it is possible to reduce the electromagnetic interference of the RF electronic devices of different frequency bands.

Meanwhile, as illustrated in FIG. 2E, in the mounting of the second electronic device, the second electronic device 21b may be mounted on the remaining lower surface area B′ other than the lower surface area A′ corresponding to the mounting area A of the first electronic device 21a of the same frequency band. Similarly, another second electronic device 22b may be mounted in the remaining lower surface area A′ other than the lower surface area B′ corresponding to the mounting area B of the first electronic device 22a of the same frequency band.

As described above, the case in which the second electronic device 21b or 22b is mounted on the lower surface 12 of the substrate 10 by the above method may have the wider separation distance for preventing the signal interference than the case in which the second electronic device 21b or 22b is mounted in the lower surface area A′ or B′ corresponding to the mounting area A or B of the first electronic device 21a or 22a.

Further, as illustrated in FIG. 2E, in the mounting of the second electronic device, the second electronic device 21b or 22b may be mounted in the lower surface area B′ or A′ corresponding to the mounting area A or B of the first electronic device 21a or 22a in a diagonal direction. Thereby, the mounting method of the present embodiment may ensure the wider separation distance.

Further, when the first electronic device 21a or 22a and the second electronic device 21b or 22b are mounted on both surfaces of the substrate 10 so as to correspond to each other in a diagonal direction, as described above, the RF paths to which the multiple input multiple output technology is applied may not be entangled with each other and thus the freedom of substrate layout may be improved.

Meanwhile, as illustrated in FIG. 2E, in the mounting of the electronic device on the lower surface of the substrate, the lower substrate 30 may be mounted along with at least one of second electronic devices 21b and 22b.

For instance, in the case of the mounting of the electronic device on the lower surface of the substrate, first, the second electronic devices 21b and 22b may be bonded on the mounting electrodes 13, and the lower substrate 30 may be bonded on one or more external connection pads 17. This process may be performed in order of bonding the second electronic devices 21b and 22b and then bonding the lower substrate 30. However, the first exemplary embodiment of the present disclosure is not limited thereto, and therefore the process may be performed by various methods, such as first bonding the lower substrate 30 or simultaneously bonding the second electronic devices 21b and 22b and the lower substrate 30.

As described above, when the second electronic devices 21b and 22b and the lower substrate 30 are mounted on the lower surface 12 of the substrate 10, heat may be applied to the solder paste P to be able to harden the solder paste P. By this process, the second electronic devices 21b and 22b and the lower substrate 30 mounted on the lower surface 12 of the substrate 10 may be firmly fixed and bonded to the substrate 10 to be electrically and physically connected to the substrate 10.

Next, as illustrated in FIG. 2F, the method of manufacturing the semiconductor package for radio communication according to the first exemplary embodiment of the present disclosure may further include forming the insulating layer 50 between the substrate 10 and the lower substrate 30. However, the first exemplary embodiment of the present disclosure is not limited thereto, and the forming of the insulating layer 50 is not necessarily performed.

The forming of the insulating layer 50 may be performed by injecting a liquid insulating material such as epoxy resin into a gap between the substrate 10 and the lower substrate 30.

That is, the insulating layer 50 may be formed by filling the gap between the substrate 10 and the lower substrate 30 with insulating material and hardening the insulating material. The substrate 10 and the lower substrate 30 may be firmly fixed and bonded to each other while being insulated from each other by the insulating layer 50.

### Second Exemplary Embodiment

### Semiconductor Package for Radio Communication

FIG. 3 is a cross-sectional view schematically illustrating a semiconductor package for radio communication according to a second exemplary embodiment of the present disclosure.

As illustrated in FIG. 3, similar to the first exemplary embodiment of the present disclosure described above, a semiconductor package 100′ for radio communication according to the second exemplary embodiment of the present disclosure may include a substrate 10′ and an electronic device 20′. For example, the semiconductor package 100′ of the second exemplary embodiment may be used in the multiple input multiple output (MIMO) system. However, the second exemplary embodiment of the present invention is not limited thereto, and therefore may be used in the single input single output (SISO) system, the single input multiple output (SIMO) system, the multiple input single output (MISO) system, and the like.

The semiconductor package 100′ for radio communication according to the second exemplary embodiment of the present disclosure is the same as or similar with the first exemplary embodiment of the present disclosure in terms of some components (a kind of substrate and electronic devices, the mounting electrode, the wiring pattern, the circuit pattern, the conductive via, the external connection pad, the lower substrate related components, the mold part, the insulating layer, and the like), and therefore the detailed description thereof will be omitted. Therefore, configurations (for example, a mounting method of the electronic devices, and the like) different from those of the semiconductor package 100 for radio communication according to the first exemplary embodiment of the present disclosure will be mainly described below.

Similar to the first exemplary embodiment of the present disclosure, a ground part 15′ may be formed on upper and lower surfaces 11′ and 12′ of the substrate 10′, that is, between both surfaces of the substrate 10′ according to the second exemplary embodiment of the present disclosure.

Further, similar to the first exemplary embodiment of the present invention, the electronic devices 20′ according to the second exemplary embodiment of the present invention may be mounted on both surfaces 11′ and 12′ of the substrate 10′. The electronic devices 20′ may be mounted on both surfaces of the substrate 10′ in various forms according to the size or shape of the electronic devices 20 or the design of the semiconductor package 100′ for radio communication.

According to the semiconductor package 100′ for radio communication according to the second exemplary embodiment of the present disclosure, at least one electronic device′ 20 may be mounted on the upper and lower surfaces 11′ and 12′ of the substrate 10′, respectively, such that the plurality of electronic devices 20′ may be mounted on both surfaces of the substrate 10′.

In this case, according to the semiconductor package 100′ for radio communication according to the second exemplary embodiment of the present disclosure, similar to the first exemplary embodiment of the present disclosure, electronic devices 21a′ and 21b′ and 22a′ and 22b′ of the same frequency band among the plurality of electronic devices 20′ may be separately mounted on both surfaces of the substrate 10′.

In the second exemplary embodiment of the present disclosure, the electronic devices mounted on the upper surface 11′ of the substrate 10′ may be defined as “first electronic devices” 21a′ and 22a′, and the electronic devices mounted on the lower surface 12′ of the substrate 10′, using the same frequency band, may be defined as “second electronic devices” 21b′ and 22b′. For example, similar to the first exemplary embodiment of the present disclosure, in the second exemplary embodiment of the present disclosure, the electronic devices 21a′ and 21b′ may run on the 5 GHz band, and the electronic devices 22a′ and 22b′ may use the 2 GHz band, but is not limited thereto and therefore may adopt all the electronic devices of various frequency bands.

According to the second exemplary embodiment of the present disclosure having the configuration as described above, the RF electronic devices of the same frequency band may be separately mounted on both surfaces of the substrate 10′, which may have a wider separation distance for preventing a signal interference than the case in which the RF electronic devices running on the same frequency band are mounted on the same one surface of the substrate.

Therefore, when the semiconductor package 100′ for radio communication according to the second exemplary embodiment of the present disclosure is applied to the multiple input multiple output technology (technology of simultaneously transmitting and receiving a signal of the same frequency band), the signal interference in the same frequency band may be minimized.

Further, according to the second exemplary embodiment of the present disclosure having the configuration as described above, the electromagnetic interference of the RF electronic devices using different frequency bands may be reduced.

However, as illustrated in FIG. 3, the semiconductor package 100′ for radio communication according to the second exemplary embodiment of the present disclosure may be different from the semiconductor package 100 for radio communication according to the first exemplary embodiment of the present disclosure in that the second electronic device 21b′ may be mounted in a second surface area A′ corresponding to a mounting area A of the first electronic device 21a′ and the second electronic device 22b′ may be mounted in a second surface area B′ corresponding to a mounting area B of the first electronic device 22a′.

That is, in the case of the second exemplary embodiment of the present invention, only if the electronic devices 21a′ and 21b′ and 22a′ and 22b′ running the same frequency band are separately mounted on both surfaces of the substrate 10′, the second electronic devices 21b′ and 22b′ may be mounted anywhere on the lower surface 12′ of the substrate 10′.

The ground parts 15′ may be formed between both surfaces of the substrate 10′.

That is, the ground part 15′ formed between both surfaces of the substrate 10′ may limit the formation of a radiation pattern from the first electronic devices 21a′ and 22a′ to the second electronic devices 21b′ and 22b′ on an opposite surface thereto, and therefore the signal interference in the same frequency band may be naturally reduced.

Therefore, the semiconductor package 100′ for radio communication according to the second exemplary embodiment of the present disclosure may need not secure the wide separation distance between the first electronic devices 21a′ and 22a′ and the second electronic devices 21b′ and 22b′ of the same frequency band. If the electronic devices 21a′ and 21b′ and 22a′ and 22b′ running the same frequency band are separately mounted on both surfaces of the substrate 10′, the second electronic devices 21b′ and 22b′ may be mounted anywhere on the lower surface of the substrate 10′.

Therefore, according to the second exemplary embodiment of the present disclosure, the second electronic devices 21b′ and 22b′ may be mounted anywhere on the lower surface 12′ of the substrate 10′, and therefore the freedom of disposition design of the second electronic devices 21b′ and 22b′ may be more improved than the first exemplary embodiment of the present disclosure.

Further, according to the second exemplary embodiment of the present disclosure, the ground part 15′ may reduce the interference of the RF signals regardless of the physical separation distance between the first electronic devices 21a′ and 22a′ and the second electronic devices 21b′ and 22b′. Accordingly, the thickness of the substrate 10′ of the second embodiment may be smaller than that of the first exemplary embodiment of the present disclosure. Therefore, the semiconductor package 100′ for radio communication according to the second exemplary embodiment of the present disclosure may be more advantageous in product miniaturization than the semiconductor package 100 for radio communication according to the first exemplary embodiment of the present disclosure.

<Method of Manufacturing Semiconductor Package for Radio Communication>

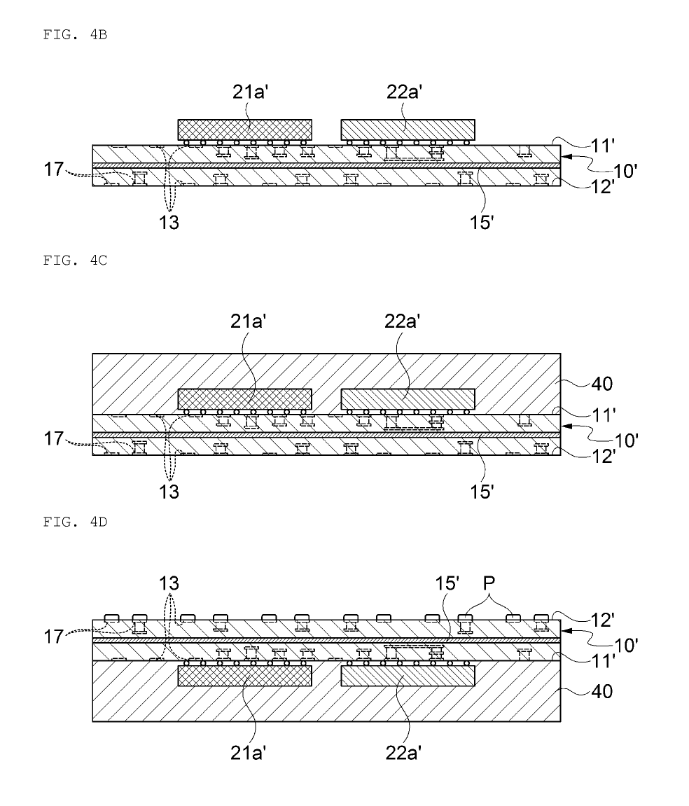

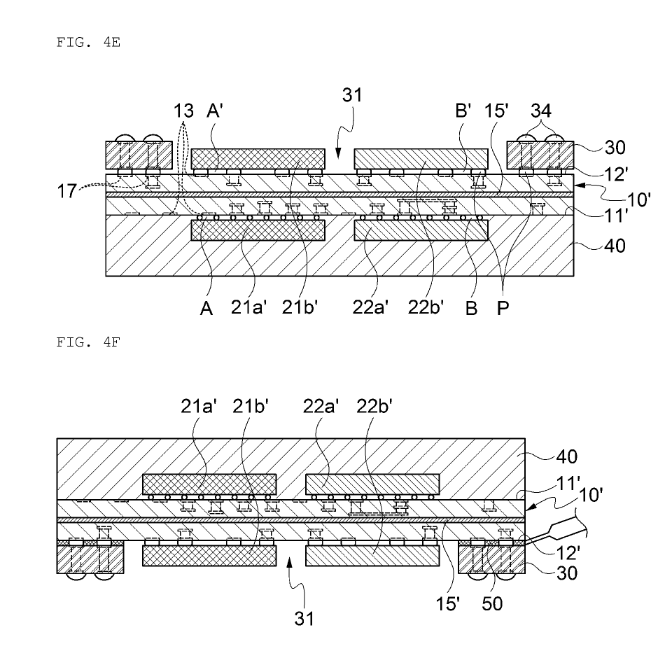

FIGS. 4A to 4F are cross-sectional views for describing a method of manufacturing the semiconductor package for radio communication according to the second exemplary embodiment of the present disclosure.

As illustrated in FIGS. 4A to 4F, similar to the first exemplary embodiment of the present disclosure, the method of manufacturing the semiconductor package according to the second exemplary embodiment of the present disclosure may include preparing the substrate 10′, mounting the electronic devices 20′ on the upper and lower surfaces 11′ and 12′ of the substrate 10′, and the like. For example, the method of the second exemplary embodiment may be used in manufacturing the multiple input multiple output (MIMO) system. However, the second exemplary embodiment of the present disclosure is not limited thereto, and therefore may be used in the single input single output (SISO) system, the single input multiple output (SIMO) system, the multiple input single output (MISO) system, and the like.

The method of manufacturing the semiconductor package for radio communication according to the second exemplary embodiment of the present disclosure are the same as or similar with the first exemplary embodiment of the present disclosure in terms of some processes (preparing the substrate, mounting the electronic device on the upper surface, forming the mold part, printing the solder paste, forming the insulating layer, and the like). Accordingly, the detailed description thereof will be omitted. Therefore, configurations (in particular, mounting the second electronic devices, and the like) different from those of the method of manufacturing the semiconductor package for radio communication according to the first exemplary embodiment of the present disclosure will be mainly described below.

First, as illustrated in FIG. 4A, the method of manufacturing the semiconductor package for radio communication according to the second exemplary embodiment of the present invention may include preparing the substrate 10′.

Further, the preparing of the substrate may further include forming the ground part 15′ between the upper surface 11′ and the lower surface 12′ of the substrate 10′. Therefore, the ground part 15′ may be formed between both surfaces of the substrate 10′ according to the second exemplary embodiment of the present disclosure.

Meanwhile, similar to the first exemplary embodiment of the present disclosure, as illustrated in FIGS. 4B and 4E, the method of manufacturing the semiconductor package for radio communication according to the second exemplary embodiment of the present disclosure may include mounting at least one or more electronic devices, for instance, the first electronic devices 21a′ and 22a′ on the upper surface 11′ of the substrate 10′ and mounting at least one or more electronic devices, for example, the second electronic devices 21b′ and 22b′ on the lower surface 12′ of the substrate 10′.

In the method of manufacturing the semiconductor package for radio communication as described above, in particular, by the mounting of the electronic devices on the upper surface and the lower surface, the electronic devices 21a′ and 21b′ and 22a′ and 22b′ using the same frequency band among the plurality of electronic devices 20′ may be separately mounted on the upper and lower surfaces (that is, both surfaces) of the substrate 10′.

As a result, according to the second exemplary embodiment of the present disclosure as described above, the RF electronic devices running on the same frequency band may be separately mounted on both surfaces of the substrate 10′, which may have a wider separation distance for preventing the signal interference than the case in which the RF electronic devices using the same frequency band are mounted on the same one surface of the substrate.

Therefore, when the method of manufacturing the semiconductor package for radio communication according to the second exemplary embodiment of the present disclosure is applied to the multiple input multiple output technology (technology of simultaneously transmitting and receiving a signal of the same frequency band), the signal interference in the same frequency band may be minimized.

Further, according to the method of manufacturing the semiconductor package for radio communication according to the second exemplary embodiment of the present disclosure, similar to the first exemplary embodiment of the present invention, it is possible to reduce the electromagnetic interference of the RF electronic devices of different frequency bands.

However, as illustrated in FIG. 4E, the method of manufacturing the semiconductor package for radio communication according to the second exemplary embodiment of the present disclosure may be different from the method of manufacturing the semiconductor package for radio communication according to the first exemplary embodiment of the present disclosure in that the second electronic device 21b′ may be mounted in the second surface area A′ corresponding to the mounting area A of the first electronic device 21a′ and the second electronic device 22b′ may also be mounted in the second surface area B′ corresponding to the mounting area B of the first electronic device 22a′.

That is, in the second exemplary embodiment of the present disclosure, if the electronic devices 21a′ and 21b′ and 22a′ and 22b′ using the same frequency band are separately mounted on both surfaces of the substrate 10′, the second electronic devices 21b′ and 22b′ may be mounted anywhere on the lower surface 12′ of the substrate 10′.

The mounting method may comprise the step of forming the ground parts 15′ between both surfaces of the substrate 10′ in the preparing of the substrate.

The ground part 15′ formed between both surfaces of the substrate 10′ may limit the formation of a radiation pattern from the first electronic devices 21a′ and 22a′ to the second electronic devices 21b′ and 22b′ on an opposite surface thereto, and therefore the signal interference in the same frequency band may be naturally reduced.

Therefore, in the case of adopting the semiconductor package 100′ for radio communication according to the second exemplary embodiment of the present disclosure, the wide separation distance between the first electronic devices 21a and 22a and the second electronic devices 21b and 22b of the same frequency band need not be secured. If the electronic devices 21a′ and 21b′ and 22a′ and 22b′ running of the same frequency band are separately mounted on both surfaces of the substrate 10′, the second electronic devices 21b′ and 22b′ may be mounted anywhere on the lower surface of the substrate 10′.

Therefore, according to the manufacturing method according to the second exemplary embodiment of the present disclosure, as described above, the second electronic devices 21b′ and 22b′ may be mounted anywhere on the lower surface 12′ of the substrate 10′, and therefore the freedom of disposition design of the second electronic devices 21b′ and 22b′ may be more improved than the manufacturing method according to the first exemplary embodiment of the present disclosure.

Further, according to the manufacturing method according to the second exemplary embodiment of the present disclosure, the ground part 15′ may reduce the interference of the RF signals regardless of the physical separation distance between the first electronic devices 21a′ and 22a′ and the second electronic devices 21b′ and 22b′. Accordingly, the thickness of the substrate 10′ may be smaller than that of the first exemplary embodiment of the present invention. Therefore, as described above, the manufacturing method according to the second exemplary embodiment of the present disclosure may be more advantageous than the manufacturing method according to the first exemplary embodiment of the present disclosure in terms of the product miniaturization.

As described above, according to some exemplary embodiments of the present disclosure, it is possible to have the wider separation distance between the RF electronic devices of the same frequency band by separately mounting the RF electronic devices of the same frequency band on both surfaces of the substrate, thereby minimizing the signal interference in the same frequency band.

In the present specification, ‘one embodiment’ of principles of the present invention and various changes of the expression means that specific features, structures, characteristics, and the like, associated with the embodiment are included in at lease one embodiment of the principle of the present invention. Therefore, the expression ‘one embodiment’ and any other modification examples disclosed throughout the present specification do not necessarily mean the same embodiment.

The drawings of the present disclosure describe the processes but illustrate the specific processes to obtain the preferred results and therefore it should not be construed that the processes need to be performed or all the illustrated processes need to be performed. In the specific case, it is advantageous to perform multitasking and parallel processes.

In the present specification, in the case of ‘at least one of A and B’, expression of ‘at least one of˜’ is used to include only selection of a first listed option A, only selection of a second listed option B, or selection of both options A and B. As an additional example, the case of ‘at least one of A, B, and C’ may include only selection of the first listed option A, only selection of the second listed option B, only selection of the third listed option C, only of the first and second listed options A and B, only selection of the second and third listed options B and C, or all the three options A, B, and C. Even in the case in which more items are listed, they may be more clearly and extensively analyzed by those skilled in the art.

Hereinabove, the present disclosure has been described with reference to exemplary embodiments thereof. All the embodiments and conditional examples disclosed in the present specification are described to help a person having ordinary skilled in the art to which the present invention pertains to understand the principle and concept of the present invention and those skilled in the art may be understood that the present invention may be implemented in a modified form within a range which does not deviating from the essential characteristics of the present invention. The scope of the present invention should be defined by the following claims rather than the above-mentioned description, and all technical spirits equivalent to the following claims should be interpreted as being included in the present disclosure.

What is claimed is:

1. A semiconductor package for radio communication, the semiconductor package comprising:
a substrate; and
a plurality of electronic devices mounted on both surfaces of the substrate,
wherein the electronic devices using the same frequency band among the plurality of electronic devices are separately mounted on the both surfaces of the substrate.

2. The semiconductor package according to claim 1, further comprising a ground part formed between the both surfaces of the substrate.

3. The semiconductor package according to claim 1, wherein the electronic devices using the same frequency band include:
a first electronic device mounted on a first surface of the both surfaces of the substrate; and
a second electronic device mounted on a second surface of the both surfaces of the substrate, and
wherein the second electronic device is mounted on the second surface other than an area of the second surface corresponding to an area of the first surface where the first electronic device is mounted.

4. The semiconductor package according to claim 3, wherein the first electronic device and the second electronic device are mounted on the first surface and the second surface, respectively, in a diagonal direction to each other.

5. The semiconductor package according to claim 3, wherein the ground part is formed between the first surface and the second surface of the substrate.

6. The semiconductor package according to claim 1, further comprising:
a lower substrate having a cavity formed therein and bonded to one of the both surfaces of the substrate so that the electronic devices mounted on the one of the both surfaces of the substrate are received in the cavity.

7. The semiconductor package according to claim 6, wherein the lower substrate is formed to be thicker than a mounting height of the electronic devices mounted on the one of the both surface of the substrate.

8. A multiple input multiple output (MIMO) system comprising the semiconductor package for radio communication of claim 1.

9. A method of manufacturing a semiconductor package for radio communication, the method comprising:
preparing a substrate;
mounting at least one or more electronic devices on an upper surface of the substrate; and
mounting at least one or more electronic devices on a lower surface of the substrate,
wherein the electronic devices using the same frequency band are separately mounted on the upper and lower surfaces of the substrate.

10. The method according to claim 9, wherein the preparing of the substrate includes forming a ground part between the upper and lower surfaces of the substrate.

11. The method according to claim 9, wherein:
the mounting of the electronic devices on the upper surface includes mounting a first electronic device on the upper surface of the substrate,
the mounting of the electronic devices on the lower surface includes mounting a second electronic device using the same frequency band as the first electronic device on the lower surface of the substrate, and
the second electronic device is mounted on the lower surface other than an area of the lower surface corresponding to an area of the upper surface where the first electronic device is mounted.

12. The method according to claim 11, wherein in the mounting of the second electronic device, the first electronic device and the second electronic device are mounted on the upper surface and the lower surface, respectively, in a diagonal direction to each other.

13. The method according to claim 11, wherein the preparing of the substrate includes forming a ground part between the upper and lower surfaces of the substrate.

14. The method according to claim 9, further comprising mounting a lower substrate on the lower surface of the substrate along with the one or more electronic devices.

15. The method according to claim 14, wherein in the mounting of the lower substrate, the one or more electronic devices are mounted so that the one or more electronic devices are received in a cavity formed in the lower substrate.

16. The method according to claim 15, wherein the lower substrate is formed to be thicker than a mounting height of the one or more electronic devices.

17. The method according to claim 9, wherein the method of manufacturing the semiconductor package for radio communication is used in a multiple input multiple output (MIMO) system.
